(19) United States
(12) Patent Application Publication
(10) Pub. No.: US 2007/0215883 A1
(43) Pub. Date: Sep. 20, 2007

(54) Electroluminescent Devices, Subassemblies for use in Making Electroluminescent Devices, and Dielectric Materials, Conductive Inks and Substrates Related Thereto

(76) Inventors: Michael John Dixon, Richmond, KY (US); Jeanne Marie Saldanha, Lexington, KY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(21) Appl. No.: 11/277,009

(22) Filed: Mar. 20, 2006

(51) Int. Cl. H01L 33/00

(52) U.S. Cl. 257/80

(57) ABSTRACT

Electroluminescent devices, subassemblies for use in making electroluminescent devices, and dielectric materials, conductive inks and substrates for use in making such subassemblies. One such electroluminescent device includes a first subassembly having an emitter layer for emitting light upon the application of an electric field and a first conductive layer adjacent a first side of the emitter layer and being substantially transparent. Such a device also includes a second subassembly having a second conductive layer and a patterned dielectric layer printed adjacent the second conductive layer. At least one of the conductive layers is formed in a pattern. The first subassembly and the second subassembly are joined to provide a circuit capable of causing electroluminescence by the emitter layer in a pattern defined, at least in part, by the pattern of at least one of the conductive layers and the patterned dielectric layer.

### TECHNICAL FIELD

This invention relates to luminous displays, specifically electroluminescent displays, that may be readily customized and/or modified by an end user.

### BACKGROUND OF THE INVENTION

In electroluminscence (EL), light is produced by applying an electric field upon an emitter material. Applying this field upon the emitter supplies the material with energized electrons that can then decay to produce photons. This results in devices that can be used for illumination. The structure of these devices can be relatively simple, such as containing two electrodes, an emitter layer and some passivation layers. There may also be other dielectric or transport layers as deemed necessary in particular applications. Conventionally, these layers are assembled by a manufacturer (sometimes according to designs specified by an end user) and the completed EL device is purchased by an end user. Since such devices are typically made without direct involvement of the end user, the end user may have a limited selection and/or ability to change aspects of the device. A need exists for such devices that can be readily customized/modified by a user, preferably at low cost.

In addition, it is often desired to have an EL device that illuminates, for example, a graphic image, such as text and/or a picture. It is known that such images can be produced by patterning one or both of the electrodes of the EL display. Understandably, since the device operates by virtue of an electric field, there must be contact between the various portions (e.g., objects and/or letters) of a given patterned electrode that are to cause illumination. Unfortunately, the contact (or bridge) between these portions also tends to cause a corresponding illumination. Still further, as conventional displays (particularly displays that could be readily customized or modified by a user) can only afford for a binary representation of brightness in the image (i.e., either the image is illuminated or it is not), images with different tones, like a grayscale image (e.g., a representation of a photograph), are not readily produced. Accordingly, a need also exists for a user customizable/rnodifiable devices such as that desired above, that can desirably illuminate graphic images.

U.S. Pat. No. 5,660,573 (the '573 patent), issued to Butt, discloses an EL lamp having continuous electrodes (i.e., not patterned or segmented) that can purportedly produce complex graphic images, but it does not appear to be readily customized or modified by an end user, particularly at a low cost. More specifically, as illustrated by the '573 patent, it is known to overly select portions of a dielectric layer with a patterned insulating layer to reduce the electric field across the selected portions of the EL dielectric layer. For example, in a first embodiment of the '573 patent, a low dielectric constant ink is printed on a dielectric layer to form chemically stable islands/areas of insulation. In another embodiment, different insulating areas are deposited on an EL layer prior to deposition of a dielectric layer. From inspection of the figures accompanying these embodiments (FIGS. 1 and 8 of the '573 patent), the respective islands/areas appear to be of the same thickness and the embodiments do not appear to relate to gray scale imaging.

In its embodiments purportedly pertaining to gray scale imaging, the '573 patent discloses depositing or printing more than one thickness of the insulating layer on the dielectric layer to produce a gray scale, wherein the number of brightness levels depends upon the number of different thicknesses of insulating material. According to the '573 patent, this is accomplished by using consecutive deposits to build up successive layers of insulating material. In particular, it discusses printing and curing one layer of insulating material at a time.

In embodiments where the '573 patent does not teach using a layer of low dielectric constant insulating material to obtain a change in electric field, it suggests using a single dielectric layer having increased thickness portions for reducing the electric field in selected areas, wherein an electrode is then deposited on the dielectric layer to complete the device. The '573 patent does not disclose how such a dielectric layer might or should be produced.

As can be understood by one of ordinary skill in the art, because the gray-scale embodiments heretofore discussed with respect to the '573 patent have relied on varying thicknesses of an insulating/dielectric material, depending on the thickness of the material and the particular pattern printed, such a layer may have a substantially non-planar topography. This does not appear to present a problem with embodiments like those discussed above because the next layer in those embodiments is deposited directly thereon, such as through printing directly thereto. Accordingly, the next layer inherently conforms to the topography.

By contrast if it was desired to simply join a structure having a substantially non-planar topography to another, potentially non-nonconforming, structure, intervening air gaps may occur because of the topography. This could have deleterious effects as air is also a dielectric (having a dielectric constant of 1). Accordingly, such air gaps may have unplanned and/or undesired effects on the level of brightness of a corresponding area in the illuminated image.

Among other reasons, these issues are probably not referenced by the '573 patent because it does not contemplate an embodiment in which its lamp is made up of various subassemblies that can be individually processed, such as by an end user. Furthermore, because it suggests printing on layers (e.g., a phosphor layer or a dielectric layer of its EL dielectric layer) that correspond to those that typically make up currently available EL subassemblies, it does not appear to contemplate embodiments where such EL subassemblies might be reused, potentially further reducing costs for an end user.

The '573 patent also suggests that a gray scale can alternatively be produced in a single layer of uniform thickness from materials having different dielectric constants (e.g., where one area is formed of a material having one dielectric constant and another is formed of a different material having a different dielectric constant). As can be understood, however, providing for the same would complicate both the processing steps required to produce such a layer and require additional materials/additional costs. Furthermore, the '573 patent mentions that an insulating layer can be patterned to produce a half-tone image. Nevertheless, the '573 patent fails to discuss anything further with respect to the same. Presumably, based on its other teachings, in either of these alternative embodiments, the '573 patent would suggest printing such layers on either a dielectric layer or a phosphor layer of its EL dielectric layer.

Accordingly, a need still exists for, among other things, an easily customizable/modifiable EL display that can illuminate, for example, complex graphic images.

### SUMMARY OF THE INVENTION

In one exemplary embodiment of the invention, an electroluminescent device is provided that includes a first subassembly having an emitter layer for emitting light upon the application of an electric field and a first conductive layer adjacent a first side of the emitter layer and being substantially transparent. The device also includes a second subassembly having a second conductive layer and a patterned dielectric layer printed adjacent the second conductive layer. At least one of the conductive layers is formed in a pattern. The first subassembly and the second subassembly are joined to provide a circuit capable of causing electroluminescence by the emitter layer in a pattern defined, at least in part, by the pattern of the at least one of the conductive layers and the patterned dielectric layer.

In another exemplary embodiment of the present invention, a subassembly is provided for use in making an electroluminescent display. One such subassembly includes a conductive layer and a patterned dielectric layer printed adjacent the conductive layer. Such a subassembly is capable of being joined with another subassembly to provide a circuit capable of causing electroluminescence by an emitter layer in a pattern, wherein the other subassembly comprises the emitter layer and another conductive layer adjacent a first side of the emitter layer and being substantially transparent, wherein at least one of the conductive layers is formed in a pattern, and wherein the electroluminescence pattern is defined, at least in part, by the pattern of the at least one of the conductive layers and the patterned dielectric layer.

Still another exemplary embodiment of the present invention involves another subassembly for use in making an electroluminescent display. One such subassembly includes an emitter layer for emitting light upon the application of an electric field and a conductive layer adjacent a first side of the emitter layer and being substantially transparent. Such a subassembly is capable of being joined with another subassembly to provide a circuit capable of causing electroluminescence by the emitter layer in a pattern, wherein the other subassembly comprises another conductive layer and a patterned dielectric layer printed adjacent the other conductive layer, wherein at least one of the conductive layers is formed in a pattern, and wherein the electroluminescence pattern is defined, at least in part, by the pattern of the at least one of the conductive layers and the patterned dielectric layer.

Yet further exemplary embodiments of the invention involve dielectric materials, conductive inks and substrates for use in various other embodiments of the invention.

### BRIEF DESCRIPTION OF THE DRAWINGS

While the specification concludes with claims particularly pointing out and distinctly claiming the present invention, it is believed the same will be better understood from the following description taken in conjunction with the accompanying drawings wherein like numerals indicate corresponding elements and wherein:

FIG. 1 illustrates a basic electroluminescent device, not to scale, and consistent with an exemplary embodiment of the present invention;

FIG. 2 illustrates two subassemblies of a device such as that illustrated in FIG. 1, not to scale, and their combination in accordance with an exemplary embodiment of the present invention; and

FIG. 3 is a business flow diagram illustrating an illustrative application of one embodiment of this invention.

### DESCRIPTION OF EXEMPLARY EMBODIMENTS

Exemplary embodiments of the present invention are described and illustrated below. Of course, it will be apparent to those of ordinary skill in the art that the embodiments discussed below are exemplary in nature and may be reconfigured without departing from the scope and spirit of the present invention. In addition, those of ordinary skill will readily comprehend various devices that may be fabricated in accordance with the methods discussed herein and, therefore, the disclosure is not limited to the exemplary embodiments discussed herein, as these embodiments are for purposes of illustrating the invention only. However, for clarity and precision, the exemplary embodiments as discussed below may include optional steps or features that one of ordinary skill will recognize as not being a requisite to fall within the scope of the present invention.

An exemplary electroluminescent device 1 is represented illustratively in FIG. 1. The exemplary device 1 comprises subassemblies 15 and 17. Using the orientation of FIG. 1 as a reference, subassembly 15 may have a top layer 3, which may be a substrate layer for supporting some of the layers to be described later, and may comprise, for example, glass or a substantially transparent polyester. The next layer from the top is layer 5, which is typically a substantially continuous and substantially transparent conductive layer. Various very thin metals and alloys, such as indium tin oxide, are examples of materials that can be used form such a substantially transparent conductive layer.

Adjacent to layer 5 is layer 7. In the depicted exemplary embodiment, layer 7 is an emitter layer, which may be comprised of a phosphorescent material suspended in a resin matrix, for example. Representative phosphorescent materials are ZnS:Cu, Al (zinc sulfide doped with copper and aluminum) and ZnS:Cu, Mn (zinc sulfide doped with copper and manganese). Meanwhile, adjacent layer 7 is layer 9. In the depicted exemplary embodiment, layer 9 is a dielectric layer, such as one that serves to physically protect emitter layer 7 while still passing electrical drive signals through its dielectric characteristics. One such suitable dielectric layer may comprise ceramic particles such as barium titanate suspended in a binder matrix.

In one embodiment of the invention, a subassembly 15 is formed in a conventional coating process, as known in the industry. Subassemblies such as these (which are referred to hereinafter, by example, as a precoated sheet) are currently available as a supply item from various manufacturers, such as BKL Inc. Graphic Solutions International, LLC, 311 Shore Drive, Burr Ridge, Ill. 60527. In an exemplary embodiment of the present invention, such precoated sheets may be made available to an end user as a supply item.

Other embodiments of the present invention might utilize a subassembly that only comprises layers such as layers 3, 5, and 7, wherein a layer such as layer 7 is printed onto a layer such as layer 5 to form a subassembly substantially equivalent to subassembly 15. As can be understood, the subassembly could also contain fewer or more layers. The choice of which layers are included in the subassembly (which may be acquired on the open market) might be governed by materials cost, sourcing, as well as the desired functionality of the resulting device.

Referring now to subassembly 17, in an exemplary embodiment of the present invention, a conductive layer 13 is formed in a pattern supported by a substrate 11. In a particular exemplary embodiment, conductive layer 13 may be formed using an inkjet ink that includes conductive particles distributed throughout a carrier fluid, although other techniques for forming the conductive layer may be used in different embodiments. The conductive particles comprise one or more materials operative to conduct electrical current; i.e., materials having a relatively low resistance to the flow of electric current. Thus, the conductive particles may be chosen from a plethora of conductive materials, where for inkjet printing the conductive material is reduced to particles having sizes less than or equal to the maximum jettable size as dictated by the nozzle exit diameter and flow features of the printhead (e.g., particles less than about 0.4 um might be used with nozzles that have exit diameters on the order of 10 um). Otherwise, the particles will be too large and potentially plug the plumbing of any inkjet conduits feeding the nozzles. The carrier fluid in which the conductive particles are disbursed may be organic or inorganic, polar or non-polar, and, for purposes of explanation only, is a water-based fluid in the exemplary embodiments. However, solvent based inks may also be used, such as when using printing devices that utilize piezoelectric actuators.

Exemplary conductive inks include platinum, nickel, bismuth, silver inks, and gold inks. Gold, silver, platinum, nickel, and bismuth aqueous dispersions are available from, for example, Nippon Paint Co., LTD. and Cima NanoTech, Inc. (www.cimananotech.com). Inks may be formulated using these aqueous dispersions in accordance with methods such as those referenced in commonly assigned U.S. patent application Ser. No. 10/985,708, filed on Nov. 10, 2004, entitled “Thermal Printing of Silver ink”, the relevant disclosure of which is hereby incorporated by reference. For purposes of explanation, conductive particles will generally have particle sizes ranging between about five and about two hundred nanometers. Nevertheless, as previously referenced, when using an inkjet printing technique, the particle size should be compatible with the dimensions of the nozzle openings of the inkjet printing device to ensure that large particles do not clog the nozzles.

Meanwhile, substrate 11 may be, for example, a silicon-based, polymer-based, cellulose-based, and/or glass-based material, such as ordinary or porous paper, or a synthetic polymer, such as a MYLAR polyester film or other polymeric films. For purposes of explanation only, the substrate 11 discussed in this exemplary embodiment includes highly uniform ceramic particles arranged on the surface of a cellulose-based backer. Meanwhile, exemplary substrates 111 having a dual layer structure include, without limitation, premium photo glossy paper commercially available from Pictorico Corporation, www.pictorico.com. One particular exemplary substrate may comprise PICTORICO Premium Photo Glossy Paper (SKU#00818) from AGA Chemicals, Inc. 2201 Water Ridge Pkwy. Ste. 400, Charlotte, N.C. 28217. Substrate 11 may be temporary and thereby later removed from a subassembly and/or device, and does not necessarily comprise a component of subassembly 17 or exemplary device 1. In addition, according to an exemplary embodiment of the present invention, a substrate such as substrate 11 and/or the conductive material (whether alone or in a bottle or printhead, for example) may be made available to an end user as a supply item.

Accordingly, an inkjet printer (not shown) can be utilized to deposit droplets of a conductive ink onto or adjacent the substrate 11 in a pattern to create the conductive layer 13. The pattern might derive from the orientation established by a programmer and automatically rendered by a computer software package after the programmer inputs a series of design rules providing a metes and bounds for the layout of the pattern. The computer software package compiles an electronic design file with instructions specific to a printer engine, where the instructions characterize the location (in two dimensions) upon the substrate 11 where conductive ink should be deposited to eventually form the conductive layer 13. Those of ordinary skill should be familiar with the computer software packages and the general concept of design rules sufficient to program and bring about an electronic representation of an exemplary printed conductive pattern by following the teachings of the present invention.

In accordance with the instructions embedded in an exemplary electronic design file, the printer engine of the inkjet printer (or any other inkjet printing device) orients at least one of the substrate 11 and the printer nozzles (e.g., on a printhead installed in the printer) to initiate the deposition sequence. Once the printer nozzles are oriented with respect to the substrate 11 at a starting location, the deposition instructions are carried out by the printer to selectively deposit droplets of conductive ink onto the substrate 11, thereby forming the conductive layer on the top of the substrate 11. To the extent any other materials are deposited by the same or a similar printing device, such a printing device may operate similarly with respect to that material, and may even utilize the same (or a different) design file.

In any event, regardless of how conductive layer 13 is formed, a dielectric material is digitally printed adjacent (e.g., on) at least a portion of the conductive layer 13 in a pattern to form patterned dielectric layer 12. The patterns of the dielectric and conductive layers may be defined independently from one another (i.e., the pattern of dielectric layer 12 is not necessarily the same as the pattern of conductive layer 13). In an exemplary embodiment, the thickness of layer 12 is less than about 20 micrometers. In still further exemplary embodiments, the thickness of layer 12 is less than about 10 micrometers. Although only laser and inkjet techniques for printing the dielectric material are specifically described below, as can be understood by one of ordinary skill in the art, other printing techniques can be used to form a patterned dielectric layer, such as silkscreen, gravure, contact roll or any other printing technique capable of printing a material with dielectric properties.

In an exemplary embodiment, the dielectric material may comprise, for example, one of an electrophotographic (laser) printable material (e.g., a toner) and an inkjet printable dielectric material (e.g., an ink). Moreover, according to an exemplary embodiment of the present invention, such a dielectric material (whether alone or in a bottle or printhead, for example) may be made available to an end user as a supply item. Using an ink to form patterned dielectric layer 12 may allow for a thinner layer (e.g., typically about 0-6 microns) than what might be provided by using a toner to form the layer (e.g., typically about 7 microns or less). The non-contact nature of inkjet printing also allows for thickness control through ink quantity deposited at a particular location whereas toner must go through a contact fuser limiting the thickness control. Minimizing the thickness of patterned dielectric layer 12 may help minimize the effect of any air gaps that might form between subassemblies 15 and 17 if and when they are joined (because air is also a dielectric, an air gap in an area may also diminish the brightness of any corresponding illuminated areas).

Suitable inkjet printable dielectric materials may comprise, for example, jettable epoxies, acrylics, urethanes, melamine formaldehyde and the like. For example, a dielectric ink may be comprised of a jettable emulsion/dispersion of polymeric particles in a carrier fluid so that when the ink is deposited onto portions of the conductive layer 13, the carrier fluid is drawn away from the polymeric particles, thereby allowing polymeric particles to coalesce and form a film as subsequent deposition occurs at a given location. Exemplary dielectric inks for use with the present invention include, without limitation:

(One Part System Containing Both Blocked Isocyanate and Polyol/Acrylic Acid Components):

| Ingredient | Example | Percentage |
|---|---|---|
| Blocked isocanate | Bayhydur ® VP LS 2310 | 8% |
| Polyol/Acrylic Acid | Joncryl ® 678 | 4% |
| Dispersant | JS1329A | 0.8% |
| Surfactant | Surfynol ® 465 | 1% |
| Co-solvent 1 | Propylene glycol | 10% |
| Co-solvent 2 | Poly(ethylene glycol) MW 200 | 5% |
| Balance D.I. Water | | |

Two Part System: Separate Ink Formulation Containing Isocyanate Component

| Ingredient | Example | Percentage |
|---|---|---|
| Blocked isocanate | Bayhydur ® VP LS 2310 | 10% |
| Dispersant | JS1329A | 0.8% |
| Surfactant | Surfynol ® 465 | 1% |
| Co-solvent 1 | Propylene glycol | 10% |
| Co-solvent 2 | Poly(ethylene glycol) MW 200 | 5% |
| Balance D.I. Water | | |

Two Part System: Ink Formulation Containing Polyol/Acrylic Acid Component

| Ingredient | Example | Percentage |
|---|---|---|
| Polyol/Acrylic Acid | Macrynal ® VSM 2521 | 5% |
| Dispersant | JS1329A | 0.8% |
| Surfactant | Surfynol ® 465 | 1% |
| Co-solvent 1 | Propylene glycol | 10% |
| Co-solvent 2 | Poly(ethylene glycol) MW 200 | 5% |
| Balance D.I. Water | | |

Where:
Bayhydur® VP LS 2310 is a product of Bayer Corp.;
Joncryl 678 is a product of Johnson Polymer;
Macrynal VSM 2521 is a product of UCB;
Surfynol® 465 is a product of Dow Air Products, Corp.; and
JS1329A is a proprietary dispersant of Lexmark International, Inc., but could be substituted with a dispersant from the Joncryl family of dispersants available from SC Johnson.

Exemplary dielectric inks may be formulated, for example, by combining two groups of compounds. The first group comprises compounds with functional groups capable of reacting with active hydrogen, such as an isocyanate group. The second group comprises compounds with functional groups containing active hydrogen, such as hydroxyl, amino, thiol urethane, or urea groups (such as polyols or acrylic acids) or functional groups that can be converted into active hydrogen containing functional groups, such as carboxylic acid derivatives (such as anhydride groups).

The material selected from the second group may also act as a humectant. This is a potential advantage because humectants in the ink can improve jetting reliability; however, the presence of these compounds/additives in the final film can adversely affect its physical, chemical, and electrical properties. Most notably, this can lead to higher water uptake than is tolerable in a dielectric material and the presence of non-volatile humectants on the surface of the film. Typically these chemicals are removed by absorption in a substrate or evaporation during curing. If they can be reacted to form part of the cured film, then they should no longer be detrimental to its properties.

Crosslinking agents and crosslinkable polymers can be formulated in one part systems (single ink formulation) or two part systems (two separated ink formulations). The ratios of both crosslinker and crosslinkable materials in the exemplary formulations were calculated based on the equivalent weights necessary to achieve a 1:1 to 3:1 ratios of crosslinking-to-crosslinkable functional groups. A small amount of excess crosslinker was added to the ink formulation to react with humectant additives containing hydroxyl or active hydrogen groups. This improves the dielectric properties of the film. Crosslinking reaction occurs through deblocking when the material is heated to a temperature above the de-block temperature of the blocking agent of the blocked isocyanate. Crosslinking reaction will not occur without heating above this temperature. This is the property which allows both polyol and isocyanate groups to be present in a single formulation without reacting before being printed on the substrate. For a one part system, both blocked polyisocyanate and polyols are added to the same ink. For a two part system, blocked isocyanate and polyol are added into two separate ink formulations with the humectants, surfactants, and additives.

The dielectric inks may also include ceramic or metal oxide nano-particulates, such as, without limitation, titanium dioxide or barium titanate. Exemplary weight percentage ranges for these nano-particulates are between zero percent and twenty percent. Finally, although the exemplary dielectric materials may be jetted using, for example, a thermal inkjet printhead, an ink need not be thermally jettable to fall within the present invention. For examples piezoelectrie actuators or other actuators, such as micro-electro-mechanical systems, might be used according to various embodiments of the present invention to provide a patterned dielectric layer.

Meanwhile, laser printable dielectric materials may comprise, for example, a polyester based toner, such as 10B041M (commercially available from Lexmark International, Inc.), and a styrene butyl acrylate toner, such as NR231A (commercially available from Lexmark International Inc.). In an exemplary embodiment, a toner such as that found in a LEXMARK 15G042K black toner cartridge (used in conjunction with a LEXMARK C762 printer, both of which are commercially available from Lexmark Internationals Inc.) might be used, but any polymer based toner should work. For example, a Lexmark® C750 laser printer (not shown) programmed with the dielectric deposition instructions of an electronic design file can be utilized to deposit the dielectric material onto at least a portion of the conductive layer 13 to form patterned dielectric layer 12. Subsequent to printing the dielectric material, the material is fused at, for example. 140-185° C., such as by utilizing the fuser of the C750 (or analogous fuser of a comparable laser printer).

When a subassembly such as subassembly 15 is joined with a subassembly such as subassembly 17 (to form an EL device such as device 1) and energized, areas corresponding to the patterned dielectric layer 12 should be darker relative to those areas that do not correspond to the patterned dielectric layer (assuming a continuous conductive layer 5). Moreover, assuming the entire dielectric pattern is formed with the same material and has substantially the same thickness, a denser pattern of dielectric over a given area (e.g., where more drops of a dielectric ink were deposited per unit area) should further reduce the average electric field experienced by the emitter over this area, and hence the brightness of the emission, in the same area. Accordingly, in an exemplary embodiment, the level of darkness should be proportional to the density of the added dielectric material (and potentially the thickness, depending on the flow of ink or melted toner after the same was printed on the conductive layer, for example). Accordingly, different levels of brightness can be provided within the illuminated image.

According to one potential use of such an embodiment of the invention, a denser area of dielectric material can be applied in a pattern such that contacts between various elements (e.g., alphanumeric characters or objects in a picture) in the conductive pattern are substantially hidden in the illuminated image. Still further, according to another potential use of such an embodiment of the invention, areas of different densities of dielectric material can be applied in a pattern to represent, for example, different tones or scales of gray in an image, such as one portraying a photograph.

According to the exemplary embodiments just described, subassemblies 15 and 17 are created and/or obtained separately. The subassemblies 15 and 17 are joined by one or more of various methods to form the device 1. Such methods may involve using pressure sensitive adhesives, curable adhesives, heat sealants, and/or other mechanical joining methods, for example. Desirably, an intimate contact should be formed between these joined subassemblies as the unplanned presence of air gaps could lead to undesirable device performance.

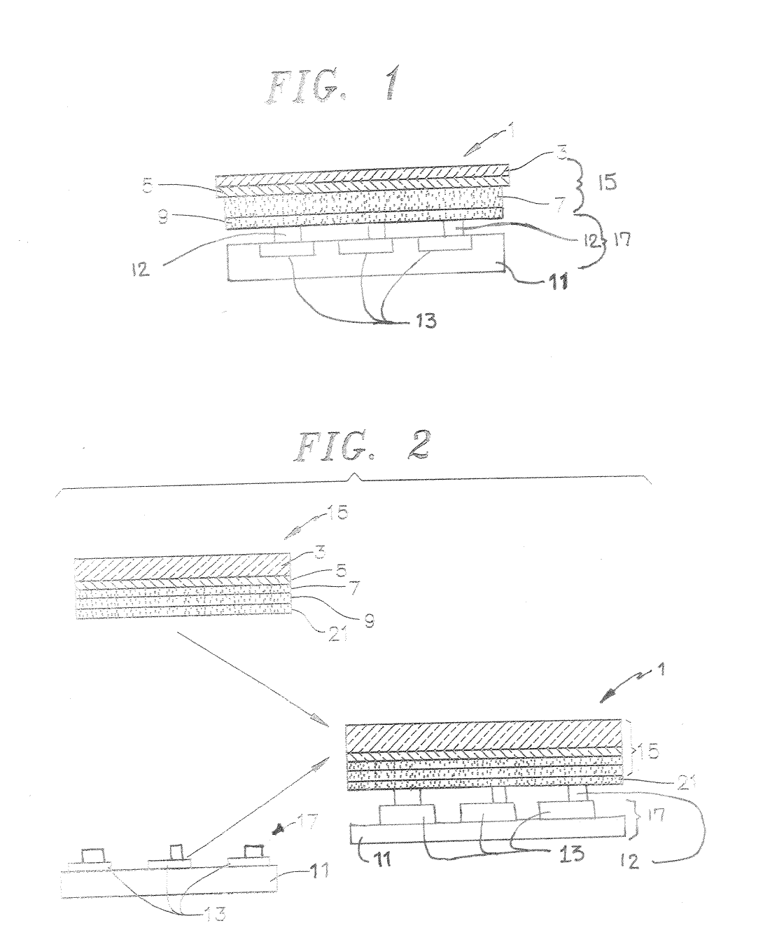

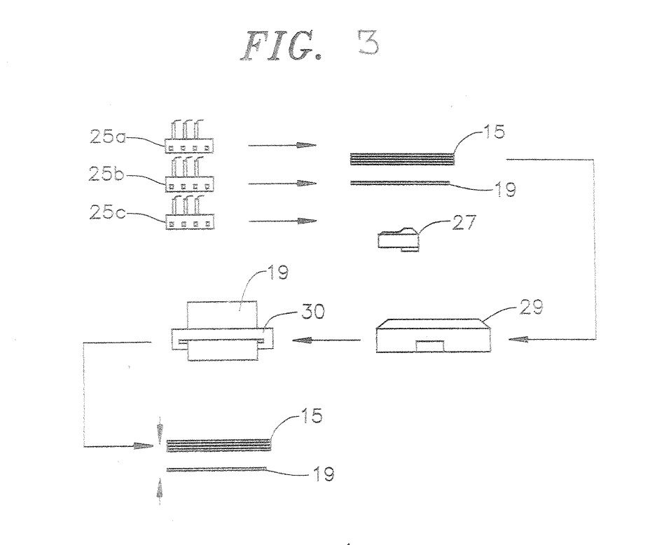

For example, in an illustrative embodiment of the present invention, methods similar to those described in co-owned U.S. patent application Ser. No. 11/209,468, filed on Aug. 23, 2005, entitled “Customizable Electroluminescent Displays,” the relevant disclosure of which is hereby incorporated by reference, may be used to join the subassemblies. Referring now to FIG. 2, extended to the previously described exemplary embodiments, one such method may involve applying an adhesive layer 21 to one of the subassemblies 15, 17 and joining the subassemblies together. Careful attention should be paid to removing as many air pockets from the joint as possible in order to achieve optimal performance. The structure of such a device is seen in FIG. 2, which depicts an embodiment in which an adhesive layer 21 is applied to subassembly 15 before joining the same to subassembly 17.

The adhesive layer 21 on subassembly 15 (or, alternatively, on subassembly 17) may be, for example, either a thermoplastic or thermosetting adhesive in the form of a liquids, paste or film. Such adhesives can be dispensed using many different techniques including, but not limited to, screen printing, stenciling, spraying, laminating, wire rod or roll coating, spin coating, inkjet, etc. The adhesives can be dispensed or placed on a surface of either subassembly 15 or subassembly 17 (or both), and the subassemblies joined together. Depending on the adhesives selected, the joined subassemblies could be exposed to various temperatures and/or pressure or other environments for intimate contact and setting or curing.

Still further exemplary embodiments might involve using mechanical means to join assemblies 15 and 17. One potential advantage of such an embodiment might include allowing a user to selectively release the mechanical joint between the assemblies, allowing subassembly 15, for example, to be reused, which may provide cost effectiveness (currently, subassemblies such as subassembly 15 are relatively more expensive than, for example, substrate 11). Various embodiments for mechanically joining assemblies such as assemblies 15 and 17 are more fully described in U.S. patent application Ser. No. 11/209,468, the relevant disclosure of which was previously incorporated by reference.

The potential business advantages and efficiencies encompassed by certain embodiments of this invention are explained further with reference to FIG. 3, which is a business-flow diagram. In particular, commercial manufacturers 25a, 25b and 25c, may make different portions of a device for commercial sale. Manufacturer 25a, for example, might produce a subassembly such as exemplary subassembly 15. Meanwhile, manufacturer 25b might produce a porous paper 19 well suited for receiving a conductive ink from an inkjet printing device, which may serve as a substrate such as substrate 11. Manufacturer 25c might produce an inkjet bottle or printhead 27 containing a silver ink and/or a dielectric ink (e.g., in different chambers of the same bottle or printhead). Of course, alternatives may exist, such as where any one of these manufacturers might produce more than one (or variations) of the above, and such as where the silver ink and dielectric ink are in separate bottles or printheads. As envisioned by an exemplary embodiment of this invention, all of these items would be readily available to the public as supply items, such as at one or more retail stores 29.

In an exemplary embodiment, the retail customer might be the end user. The retail customer could then, for example, conveniently print a desired conductive pattern on paper 19 at that person's home or business using, for example, printhead 27 in an inkjet printing device, such as inkjet printer 29 (which the end user may already have for other purposes). Likewise, the customer may similarly print a desired dielectric pattern on the conductive pattern, for example. The subassembly 15 and the paper 19 with conductive and dielectric patterns are then joined such as previously described. The resulting device is therefore conveniently and readily customized/modified as desired by the end user (in this case, the retail customer).

Following from the above description and invention summaries, it should be apparent to those of ordinary skill in the art that, while the methods and apparatuses herein described constitute exemplary embodiments of the present invention, the invention contained herein is not limited to these precise embodiments and that changes may be made to such embodiments without departing from the scope of the invention as defined by the claims. For example, an EL device may not necessarily have a dielectric layer in addition to that patterned on a conductive layer of a subassembly such as subassembly 17. Still further, although an embodiment was described above where a conductive layer such as conductive layer 13 was formed in a pattern, other embodiments might also pattern a conductive layer such as conductive layer 5, instead of and/or in addition to a layer such as conductive layer 13 (and wherein the patterns may be the same and/or different from one another).

Additionally, it is to be understood that the invention is defined by the claims and it is not intended that any limitations or elements describing the exemplary embodiments set forth herein are to be incorporated into the interpretation of any claim element unless such limitation or element is explicitly stated. Likewise, it is to be understood that it is not necessary to meet any or all of the identified advantages or objects of the invention disclosed herein in order to fall within the scope of any claims, since the invention is defined by the claims and since inherent and/or unforeseen advantages of the present invention may exist even though they may not have been explicitly discussed herein.

What is claimed is:

1. An electroluminescent device comprising:
a first subassembly comprising
an emitter layer for emitting light upon the application of an electric field; and
a first conductive layer adjacent a first side of the emitter layer and being substantially transparent; and
a second subassembly comprising
a second conductive layer; and
a patterned dielectric layer printed adjacent the second conductive layer, wherein at least one of the conductive layers is formed in a pattern and wherein the first subassembly and the second subassembly are joined to provide a circuit capable of causing electroluminescence by the emitter layer in a pattern defined, at least in part, by the pattern of the at least one of the conductive layers and the patterned dielectric layer.

2. The electroluminescent device of claim 1, wherein the first subassembly further comprises a dielectric layer adjacent the emitter layer on a side of the emitter layer opposite the first side.

3. The electroluminescent display of claim 1, wherein the first subassembly further comprises a substrate layer supporting the emitter layer and the first conductive layer, and wherein the second subassembly further comprises a substrate layer supporting the second conductive layer.

4. The electroluminescent display of claim 3, wherein the substrate of the second subassembly comprises a sheet of print media, wherein conductive ink from a printing device forms the second conductive layer on the sheet of print media.

5. The electroluminescent display of claim 4, wherein the at least one of the conductive layers in a pattern comprises the second conductive layer, which is formed by printing conductive ink from a printing device in a pattern on the sheet of print media.

6. The electroluminescent display of claim 3, wherein the substrate of the first subassembly comprises at least one of glass and a substantially transparent polyester.

7. The electroluminescent display of claim 1, wherein the first subassembly and second subassembly are adhesively joined.

8. The electroluminescent display of claim 1, wherein the first subassembly and second subassembly are mechanically joined.

9. The electroluminescent display of claim 1, wherein the first subassembly and second subassembly are selectively releasably joined.

10. The electroluminescent display of claim 1, wherein the patterned dielectric layer printed adjacent the second conductive layer comprises a layer of dielectric material printed in a pattern such that a density of the dielectric material in one area of the pattern is different than a density of the dielectric material in another area of the pattern

11. The electroluminescent display of claim 1, wherein the patterned dielectric layer is formed by printing a dielectric ink from a printing device in a pattern on the second conductive layer.

12. The electroluminescent display of claim 11, wherein the dielectric ink comprises one of jettable epoxies, acrylics, urethanes, and melamine formaldehyde.

13. The electroluminescent display of claim 1, wherein the patterned dielectric layer is formed by printing a dielectric toner from a printing device in a pattern on the second conductive layer.

14. The electroluminescent display of claim 13, wherein the dielectric toner comprises a polymer based toner.

15. The electroluminescent display of claim 1, wherein the first conductive layer comprises a substantially continuous conductive layer.

16. A dielectric material for use in making the second subassembly of the electroluminescent display of claim 1.

17. A conductive ink for use in making the second conductive layer of the electroluminescent display of claim 1.

18. A substrate for use in making the second subassembly of the electroluminescent display of claim 1.

19. A subassembly for use in making an electroluminescent display, the subassembly comprising:
a conductive layer; and
a patterned dielectric layer printed adjacent the conductive layer, wherein the subassembly is capable of being joined with an other subassembly to provide a circuit capable of causing electroluminescence by an emitter layer in a pattern, wherein the other subassembly comprises the emitter layer and an other conductive layer adjacent a first side of the emitter layer and being substantially transparent, wherein at least one of the conductive layers is formed in a pattern and wherein the electroluminescence pattern is defined at least in part, by the pattern of the at least one of the conductive layers and the patterned dielectric layer.

20. A subassembly for use in making an electroluminescent display, the subassembly comprising:
an emitter layer for emitting light upon the application of an electric field; and
a conductive layer adjacent a first side of the emitter layer and being substantially transparent,
wherein the subassembly is capable of being joined with an other subassembly to provide a circuit capable of causing electroluminescence by the emitter layer in a pattern, wherein the other subassembly comprises an other conductive layer and a patterned dielectric layer printed adjacent the other conductive layer, wherein at least one of the conductive layers is formed in a pattern, and wherein the electroluminescence pattern is defined, at least in part, by the pattern of the at least one of the conductive layers and the patterned dielectric layer.
